(19) United States
(12) Patent Application Publication
(10) Pub. No.: US 2024/0213771 A1
(43) Pub. Date: Jun. 27, 2024

(54) EQUIVALENT AGGREGATION METHOD AND APPARATUS FOR ELECTRO-THERMAL COUPLED VIRTUAL POWER PLANT

(71) Applicants: TSINGHUA UNIVERSITY, Beijing (CN); STATE GRID JIBEI ELECTRIC POWER COMPANY, Beijing (CN); STATE GRID BEIJING ELECTRIC POWER COMPANY, Beijing (CN)

(72) Inventors: Bin WANG, Beijing (CN); Xuanyuan WANG, Beijing (CN); Haotian ZHAO, Beijing (CN); Yanna XI, Beijing (CN); Bo NING, Beijing (CN); Hongbin SUN, Beijing (CN); Zhen LIU, Beijing (CN); Shu WANG, Beijing (CN); Qinglai GUO, Beijing (CN)

(21) Appl. No.: 18/457,674

(22) Filed: Aug. 29, 2023

(30) Foreign Application Priority Data
Dec. 23, 2022 (CN) 202211660208.7

(51) Int. Cl. H02J 3/00

(52) U.S. Cl. CPC H02J 3/00; H02J 2203/20

(57) ABSTRACT

The present disclosure provides an equivalent aggregation method and an apparatus for an electro-thermal coupled virtual power plant. The method includes: obtaining an equivalence model in a heating section of the electro-thermal coupled virtual power plant by training a support vector machine; establishing a computing model for equivalent aggregation of the electro-thermal coupled virtual power plant; and realizing the equivalent aggregation of the electro-thermal coupled virtual power plant by solving the computing model for the equivalent aggregation of the electro-thermal coupled virtual power plant.

### CROSS-REFERENCE TO RELATED APPLICATIONS

This application claims priority to Chinese Patent Application No. 202211660208.7, filed Dec. 23, 2022, the entire disclosure of which is incorporated herein by reference.

### TECHNICAL FIELD

The present disclosure belongs to a field of operation control technology of integrated energy systems, and relates to an equivalent aggregation method for an electro-thermal coupled virtual power plant and an equivalent aggregation apparatus for an electro-thermal coupled virtual power plant.

### BACKGROUND

In order to achieve a goal of low carbon, there is a need to construct a new power system with new energy as a main body. In the new power system, a penetration rate of new energy power generation will increase significantly, and its randomness and volatility bring great challenges to the safe and economic operation of the power system. As an important form of effective management of distributed energy access to the superior power grid, the virtual power plant aggregates a large number of distributed energy sources, controllable loads and energy storage devices into a virtual whole, to participate in the operation and scheduling of the power grid, thereby improving the safe and economic operation of the power grid, and reducing the investment costs of the power grid at the same time.

Currently, with the development of the urban centralized heating system, the electric-thermal coupling has become more and more compact, and in order to give full play to the flexibility of electric-thermal synergy, the electric-thermal coupling resources are integrated into an electric-thermal coupling virtual power plant to respond to the scheduling of the power system. The multi-energy virtual power plant equivalent aggregation technology is the basis for participation in the scheduling of the power market and the power system. However, due to the complexity of the heat transfer process in the heating section and the difficulty of accurate modeling, the purely model-driven equivalent approach may bring large errors.

The existing Chinese Patent Application No. 201911094785.2, titled “a Robust Correction-Based Method for Aggregating Operation Parameters of a Multi-Energy Virtual Power Plant”, uses a model-driven approach to perform equivalent calculation for the electric-thermal coupled virtual power plant, but this approach assumes that the heating section model parameters are known and completely accurate. However, in practice, the parameters of the heating pipe network due to differences in operating conditions, corrosion of the inner wall of the pipe section and other reasons, may be of great difference from theoretical calculation values. The use of inaccurate parameters will make the aggregation model obtained by this method less accurate and may produce power deviations of interconnection lines that do not satisfy the aggregation assessment requirements of the virtual power plant.

### SUMMARY

According to a first aspect of the present disclosure, an equivalent aggregation method for an electro-thermal coupled virtual power plant is provided. The method includes:
obtaining an equivalence model in a heating section of the electro-thermal coupled virtual power plant by training a support vector machine;
establishing a computing model for equivalent aggregation of the electro-thermal coupled virtual power plant; and realizing the equivalent aggregation of the electro-thermal coupled virtual power plant by
solving the computing model for the equivalent aggregation of the electro-thermal coupled virtual power plant.

According to a second aspect of the present disclosure, an equivalent aggregation apparatus for an electro-thermal coupled virtual power plant is provided. The apparatus includes: an equivalence model generating element, configured to obtain an equivalence model in
a heating section of the electro-thermal coupled virtual power plant by training a support vector machine;
a computing model establishing element, configured to establish a computing model for equivalent aggregation of the electro-thermal coupled virtual power plant; and
a computing model solving element, configured to realize equivalent aggregation of the electro-thermal coupled virtual power plant by solving the computing model for equivalent aggregation of the electro-thermal coupled virtual power plant.

According to a third aspect of the present disclosure, an electronic device is provided. The electronic device includes:
a memory, configured to store instructions executable by a computer;
a processor, configured to sequentially execute following operations:
obtaining an equivalence model in a heating section of the electro-thermal coupled virtual power plant by training a support vector machine;
establishing a computing model for equivalent aggregation of the electro-thermal coupled virtual power plant; and
realizing equivalent aggregation of the electro-thermal coupled virtual power plant by
solving the computing model for equivalent aggregation of the electro-thermal coupled virtual power plant.

According to a fourth aspect of the present disclosure, a non-volatile computer-readable storage medium having computer programs stored thereon is provided. The computer programs are configured to cause a computer to sequentially execute:
obtaining an equivalence model in a heating section of the electro-thermal coupled virtual power plant by training a support vector machine;
establishing a computing model for equivalent aggregation of the electro-thermal coupled virtual power plant; and
realizing equivalent aggregation of the electro-thermal coupled virtual power plant by
solving the computing model for equivalent aggregation of the electro-thermal coupled virtual power plant.

Additional aspects and advantages of the embodiments of the present disclosure will be given in part in the following descriptions, become apparent from the following descriptions, or be learned from the practice of the embodiments of the present disclosure.

### BRIEF DESCRIPTION OF THE DRAWINGS

In order to more clearly illustrate the technical solutions in the embodiments of the present disclosure, the following is a brief description of the accompanying drawings to be used in the description of the embodiments. Obviously, the accompanying drawings in the following description are only some embodiments of the present disclosure, and other accompanying drawings can be obtained by those skilled in the art according to the accompanying drawings without inventive works.

FIG. 1 is a schematic diagram of a relation between an electro-thermal coupled virtual power plant and a superior power grid according to an embodiment of the present disclosure.

FIG. 2 is a schematic diagram of an equivalent aggregation apparatus for an electro-thermal coupled virtual power plant according to an embodiment of the present disclosure.

### DETAILED DESCRIPTION

The technical solutions in embodiments of the present disclosure will be clearly and completely described below in combination with the accompanying drawings in the embodiments of the present disclosure. Obviously, the described embodiments are a part of the embodiments of the present disclosure, and not all of them. Based on the embodiments of the present disclosure, all other embodiments obtained without inventive works by those skilled in the art fall within the scope of protection of the present disclosure.

The following is a detailed description of the present disclosure in combination with the accompanying drawings of the present disclosure.

The present disclosure provides an equivalent aggregation method for an electro-thermal coupled virtual power plant, an equivalent aggregation apparatus for an electro-thermal coupled virtual power plant, an electronic device and a storage medium, which overcome the shortcomings of the existing model driving methods to obtain the parameters precisely and make the aggregation results more accurate.

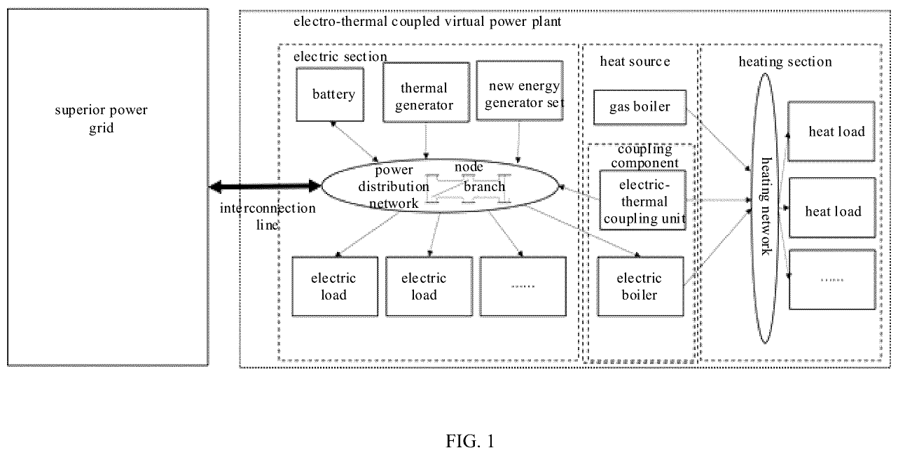

FIG. 1 is a schematic diagram of a relation between an electro-thermal coupled virtual power plant and a superior power grid according to an embodiment of the present disclosure.

In a method embodiment of the present disclosure, an equivalent aggregation method for an electro-thermal coupled virtual power plant is provided. The method includes the following steps.

In step I, an equivalence model in a heating section of the electro-thermal coupled virtual power plant is obtained by training the support vector machine. The step includes the following steps.

Based on historical operation data of the heating section of the electro-thermal coupled virtual power plant or using a heating section simulation model built by using a simulation model, N pieces of operation data of the equivalence model for training the heating section of the electro-thermal coupled virtual power plant are obtained, a data set X={X₁, X₂, . . . , X_{N}}, i.e., {Xᵢ_{_{d}}|1≤i_{d}≤N}, X₁, X₂, X_{N} is established, and heating powers and outdoor temperatures of all heat sources in the heating section at all times are selected from the operation data set X and are determined as features, in which a subscript id represents an operation data serial number, id=1, 2, . . . , N, Xᵢ_{_{d}}=[hᵢ_{_{d}}ₜ¹, hᵢ_{_{d}}ₜ², . . . , hᵢ_{_{d}}ₜ^{NHS}, τᵢ_{_{d}}ₜ]^{T}, t∈T, a superscript T represents a matrix transposition, and NHS represents a total number of heat sources in the heating section of the electro-thermal coupled virtual power plant. In embodiments of the present disclosure, there are three types of heat sources, i.e., combined heat and power components, electric boilers and gas boilers, in which h; represents a thermal output power of a jth heat source in the heating section in the idth operation data at a scheduling time t, and τᵢ_{_{d}}ₜ represents an outdoor temperature in the idth operation data at the scheduling time t.

(2) A test set is obtained from historical operation data or by the simulation model, and the test set is used for training the equivalence model in the heating section of the electro-thermal coupled virtual power plant, in which the test set is used to test an accuracy rate of the equivalence model in the heating section of the electro-thermal coupled virtual power plant based on the historical operation data of the heating section of the electro-thermal coupled virtual power plant or using the simulation model of the heating section built using the simulation model. NTE pieces of operation data are obtained, which are generally different from the above-mentioned N operation data in step (1). For different operation data, different dates is selected, and for simulation data, different results can be obtained by using different simulation conditions. A test data set X_{TE}={X₁^{TE}, X₂^{TE}, . . . , X_{N}_{_{TE}}^{TE}} is established by using the NTE operation data as test data, and heating powers and outdoor temperatures of all heat sources in the heating section at all times are determined from the test data set X_{TE} as features.

(3) Initial labels y⁰=[y₁, y₂, . . . , y_{N}]^{T} are assigned to each data in the operation data set X in step (1), in which the subscript id represents the operation data serial number, id=1, 2, . . . , N, yᵢ_{_{d}} represents a label corresponding to the idth operation data, and the superscript T represents the matrix transposition. A temperature inside all heat load chambers in the heating section of the electro-thermal coupled virtual power plant under conditions of the operation data set is judged. In case that the temperature inside all the heat load chambers reaches a temperature threshold under operation conditions corresponding to the idth operation data Xᵢ_{_{d}} label 0 is assigned to the idth operation data by yᵢ_{_{d}}=0, and in case that the temperature inside at least one heat load chamber in the electro-thermal coupled virtual power plant does not reach the temperature threshold, label 1 is assigned to the idth operation data by y=1.

(4) Labels y_{TE}=[y₁, y₂, . . . , yᵢ_{_{TE}} . . . , y_{N}]^{T} are assigned to the test data set generated in step (2), in which a subscript TE represents a test data serial number, i_{TE}=1, 2, . . . , N_{TE}, and a superscript T represents the matrix transposition, and a temperature inside heat load chambers in the heating section under operation conditions of the test data set is judged. In case that the temperature inside all the heat load chambers reaches the temperature threshold under operation conditions corresponding to the i_{TE}th test data, label 0 is assigned to the i_{TE}th test data, and in case that the temperature inside at least one heat load chamber in the electro-thermal coupled virtual power plant does not reach the temperature threshold, label 1 is assigned to the i_{TE}th test data.

An equivalence model accuracy threshold ε_{D} and a maximum training number nmax are set, and single classification training is performed on the operation data set X in step (1), which includes the following process.

A total training number is set as n=1, the operation data set X is input into a support vector machine SVM₁. Classification results for each data in the operation data set X are output by the support vector machine SVM to obtain a classification model SVM₁=(w₁, b₁), where w₁ represents a hyper-plane normal vector of the classification model in the support vector machine, and bᵢ represents a hyper-plane intercept of the classification model in the support vector machine. The support vector machine is a class of generalized linear classifiers that perform binary classification of data in a supervised learning fashion, with a decision boundary of a maximum margin hyperplane solved for learned samples, the SVMs were proposed in the 1964 at a paper Vapnik, V. and Chervonenkis, A., A note on class of perceptron on the Automation and Remote Control, 24, and subsequently developed rapidly after the 1990s and derived a series of improved and extended algorithms).

(6) The test data set X_{TE}={X₁^{TE}, X₂^{TE}, . . . , X_{N}_{_{TE}}^{TE} } generated in step (2) and the labels y_{TE}=[y₁, y₂, . . . , yᵢ^{TE}, . . . , y_{N}]^{T} assigned in step (4) are used to calculate a classification accuracy rate ε_{R} of the support vector machine SVM₁=(w₁, b₁) when n=1 by a following formula:

$${ε}_{R} = \frac{{N}_{correct}}{{N}_{total}} \times 100 \% ,$$

where Nₜₒₜₐₗ is a total number of data points in the test data set X_{IE} whose labels are 1, N_{correct} is a number of samples correctly classified, and N_{correct} is a total number of data points in the test data set X_{IE} whose labels are 1 and classified as category 1 by the classification model SVM₁.

(7) Comparing the ε_{R} with the equivalence model accuracy threshold ε_{D}, in case that ε_{R}<ε_{D} and n<nmax, step (8) is executed, and in case that ε_{R}≥ε_{D} or n≥nmax, a support vector machine SVMn is used as the equivalence model in the heating section of the electro-thermal coupled virtual power plant, and step (2) is executed.

(8) The n in step (5) is added by 1 and labels yⁿ={y₁ⁿ, y₂ⁿ, . . . , y_{N}ⁿ} are reassigned to the operation data set X in step (1), where

$${y}_{{i}_{d}}^{n} = \{ \begin{matrix}{y}_{{i}_{d}}^{n - 1} , {i}_{d} ∉ {S}_{wrong} \\ max \{ {y}_{{i}_{d}}^{n - 1} \} + 1 , {i}_{d} ∈ {S}_{wrong}\end{matrix} ,$$

S_{wrong} represents a set consisting of serial numbers of the samples classified incorrectly in step (6), and S_{wrong}={i|yᵢ⁰=1, SVMₙ(Xᵢ)<1}, id represents the data serial number of the operation data set.

(9) The operation data set X in step (1) and the labels yⁿ in step (8) are classified, to obtain an (n+1)th classification model SVMₙ₊₁=(w₁ⁿ⁺¹, b₁ⁿ⁺¹, . . . , w_{(n+1)(n+2)/2}ⁿ⁺¹, b_{(n+1)(n+2)/2}ⁿ⁺¹), where w₁ⁿ⁺¹, bᵢⁿ⁺¹ represent an ith hyper-plane normal vector and an ith hyper-plane intercept in the (n+1)th classification model, respectively.

(10) For the (n+1)th classification model SVMₙ₊₁ an accuracy rate of the (n+1)th classification model SVMₙ₊₁ is tested by using the test data set X_{TE}={X_{TE}, X_{IE}, . . . , X_{TE} } generated in step (2) and the labels y_{TE}=[y₁, y₂, . . . , y_{TE}, . . . , y_{N}]^{T} assigned in step (4), and a classification accuracy rate ε_{R} of the (n+1)th classification model SVMₙ₊₁ is calculated by V total represents a total number of data points whose labels using the method in step (6), where N correct represents a total number of data points in the test data set X are 1 in X_{IE} whose labels are 1 and classified as category 1 by the classification model SVM₁ and when SVMₙ₊₁(X)>0 and yᵢ⁰=1, the data point i is considered to be accurately classified.

(11) It is configured that n=n+1, comparing ε_{R} in step (10) with the equivalence model accuracy threshold ε_{D}, in case that ε_{R} KED and n<nmax, it is returned to step (8), and in case that ε_{R}≥ε_{D} or nenmax, using the support vector machine SVMn as the equivalence model in the heating section of the electro-thermal coupled virtual power plant, and it is returned to step (2).

In step II, the computing model for equivalent aggregation of the electro-thermal coupled virtual power plant is established, which includes the following steps.

(21) an objective function of the computing model for equivalent aggregation of the electro-thermal coupled virtual power plant is established:

$${min}_{y} {\sum }_{t ∈ ϒ} ( {c}_{t}^{p , min} {\underline{p}}_{t} - {c}_{t}^{p , max} {\overline{p}}_{t} + {c}_{t}^{e , min} {\underline{e}}_{t} - {c}_{t}^{e , max} {\overline{e}}_{t} - {c}_{t}^{r u} {r}_{t}^{u} - {c}_{t}^{r d} {r}_{t}^{d} ) + {max}_{{p}_{t}^{order} ∈ Ω} {min}_{x} {\sum }_{t ∈ ϒ} [ σ ( {δ}_{t}^{+} + {δ}_{t}^{-} ) ] ,$$

where the objective function is a maximum feasible domain of the computing model of equivalent aggregation of the electro-thermal coupled virtual power plant obtained by aggregation; parameters pₜ, p̅ₜ̅, eᵣ, rᵢ^{d}, and rᵢ^{u} represent a lower power limit, an upper power limit, a lower energy limit, an upper energy limit, a lower limit of a power change rate, and an upper limit of the power change rate of an interconnection line between the electro-thermal coupled virtual power plant and a superior power grid at the scheduling time t, respectively; cₜ^{p,min}, cᵢ^{p,max}, cᵢ^{e,min}, cᵢ^{e_max}, cᵢ^{ru}, cᵢ^{rd} represent weights of the parameters pₜ, p̅ₜ, eₜ, ēₜ, rₜ^{d}, and respectively; values of cₜ^{p,min}, c^{p,max}, cᵢ^{e,min}, cᵢ^{e_max}, cᵢ^{ru}, and cᵢ^{rd} are determined according to actual operation conditions of the superior power grid. In an embodiment of the present disclosure, since the power system may require a higher upper power limit for the electro-thermal coupled virtual power plant, c^{p,max} is taken to be a larger value of cₜ^{p,min}, cᵢ^{e,min}, cᵢ^{e_max}, cᵢ^{ru}, and cᵢ^{rd} are taken to be 10 respectively, and pₜ^{order} is an active power order is an active power value of a possible scheduling plan of the superior power grid at the scheduling time t and is a variable to be solved. {pₜ, p̅ₜ, eₜ, ēₜ, r^{u}, r^{d}} represent variables to be calculated for solving an aggregation model of the electro-thermal coupled virtual power plant, these six variables constitute the feasible domain obtained by aggregation and pₜ^{order} satisfies that pₜ≤pₜ^{order}≤p̅ₜ, t∈T,

$${\underline{e}}_{t} \leq {\sum }_{t = 1}^{t} {p}_{t}^{o r d e r} \leq {\overline{e}}_{t} , t ∈ T ,$$

and −r^{d}≤pₜ^{order}-pₜ₋₁^{order}≤r^{u}, t∈T where σ represents a large positive number, such as 106, δₜ⁺ represents an auxiliary variable for a power positive deviation of the interconnection line, δₜ⁻ represents an auxiliary variable for a power negative deviation of the interconnection line, y represents a first stage decision variable for an optimal computing model for equivalent aggregation of the electro-thermal coupled virtual power plant, and x represents a second stage decision variable for the optimal computing model. A column vector consisting of the first stage decision variables y is y=[pₜ, p̅ₜ, eₜ, ēₜ, r^{u}, r^{d}], and a column vector consisting of the second stage decision variables x is x=[pₜⁱ^{_{G}}, pₜⁱ^{_{W}}, pₜ^{CHP,i}^{_{c}}, hₜ^{CHP,i}^{_{c}}, pₜ^{c,i}^{_{E}}, pₜ^{dc,i}^{_{E}}, eₜⁱ^{_{E}}, hₜⁱ^{_{GB}}, pₜⁱ^{_{EB}}, δₜ⁺, δₜ⁻] where pₜⁱ^{_{G}} represents a power output of an iGth thermal generator in an electric section of the electro-thermal coupled virtual power plant at the scheduling time t, pₜ^{W,i}^{_{w}} represents an actual power output of an iWth new energy generator set in the electric section of the electro-thermal coupled virtual power plant at the scheduling time t, pₜ^{CHP,i}^{_{C}} and hₜ^{CHP,i}^{_{C}} represent an electricity output and a heat output of an iCth combined heat and power component in a coupling section of the electro-thermal coupled virtual power plant at the scheduling time t, respectively, pₜ^{c,i}^{_{E}} and pₜ^{dc,i}^{_{E}} represent a charging power and a discharging power of an iEth battery in the electric section of the electro-thermal coupled virtual power plant at the scheduling time t, respectively. eₜⁱ^{_{E}} represents an energy stored by the iEth battery in the electric section of the electro-thermal coupled virtual power plant at the scheduling time t; hₜⁱ^{_{GB}} represents a heating power of an iGBth gas boiler in the heating section of the electro-thermal coupled virtual power plant at the scheduling time t. pₜⁱ^{_{EB}} represents a power consumption of an iEBth electric boiler in the heating section of the electro-thermal coupled virtual power plant at the scheduling time t; and in the objective function, except for δₜ⁺, δₜ⁻, the weights of other variables in the objective function are 0.

(22) Constraints of the optimal computing model for equivalent aggregation of the electro-thermal coupled virtual power plant are established, which includes the following steps.

(221) The constrains of the electric section are:

$${p}_{t}^{tie} + {\sum }_{{i}_{G} ∈ {S}_{G}} {p}_{t}^{{i}_{G}} + {\sum }_{{i}_{W} ∈ {S}_{W}} {p}_{t}^{{i}_{W}} + {\sum }_{{i}_{C} ∈ {S}_{C H P}} {p}_{t}^{{i}_{C}} + {\sum }_{{i}_{E} ∈ {S}_{E S}} ( {p}_{t}^{dc , {i}_{E}} - {p}_{t}^{c , {i}_{E}} ) = {\sum }_{{i}_{B} ∈ {S}_{B U S}} {P}_{t}^{L , {i}_{B}} + {\sum }_{{i}_{E B} ∈ {S}_{E B}} {p}_{t}^{{i}_{E B}} , ∀ t ∈ ϒ$$

$${p}_{t}^{l , BR} = \vert {\sum }_{n ∈ {S}_{B U S}} P T D {F}_{l , {i}_{B}} \cdot {p}_{t}^{NET , {i}_{B}} \vert , ∀ l ∈ {S}_{B R} , t ∈ ϒ$$

$${p}_{t}^{NET , n} = {\sum }_{{i}_{G} ∈ {S}_{G , {i}_{B}}} {p}_{t}^{{i}_{G}} + {\sum }_{{i}_{W} ∈ {S}_{W , {i}_{B}}} {p}_{t}^{{i}_{W}} + {\sum }_{{i}_{C} ∈ {S}_{CHP , {i}_{B}}} {p}_{t}^{{i}_{C}} + {\sum }_{{i}_{E} ∈ {S}_{ES , {i}_{B}}} ( {p}_{t}^{d c , {i}_{E}} - {p}_{t}^{c , {i}_{E}} ) - {P}_{t}^{L , n} - {\sum }_{{i}_{EB} ∈ {S}_{EB , n}} {p}_{t}^{{i}_{E B}}$$

$${e}_{1}^{{i}_{E}} = {E}_{0}^{{i}_{E}} + ( {η}^{c , {i}_{E}} {p}_{1}^{c , {i}_{E}} - {p}_{1}^{d c , {i}_{E}} / {η}^{d c , {i}_{E}} ) Δ t , ∀ {i}_{E} ∈ {S}_{ES} ,$$

$${e}_{t}^{{i}_{E}} = ( 1 - {s}^{{i}_{E}} ) {e}_{t - 1}^{{i}_{E}} + ( {η}^{c , {i}_{E}} {p}_{t}^{c , {i}_{E}} - \frac{{p}_{t}^{d c , {i}_{E}}}{{η}^{d c , {i}_{E}}} ) Δ t , ∀ t ∈ ϒ ∖ \{ 1 \} , ∀ i ∈ {S}_{E S} .$$

$$0 \leq {p}_{t}^{{i}_{W}} \leq {P}_{t}^{{i}_{W} , pre}$$

$${P}_{min}^{{i}_{G}} \leq {p}_{t}^{{i}_{G}} \leq {P}_{max}^{{i}_{G}}$$

$${P}_{min}^{{i}_{E B}} \leq {p}_{t}^{{i}_{E B}} \leq {P}_{max}^{{i}_{E B}}$$

where S_{G}, S_{W}, S_{CHP}, S_{ES}, S_{L} and S_{EB} represent a collection of thermal generators, a collection of new energy generator sets, a collection of combined heat and power components, a collection of batteries, a collection of electric loads, and a collection of electric boilers in the electro-thermal coupled virtual power plant, respectively; a subscript iB of device collection represents a collection of all devices connected to a node iB of a power distribution network in the electric section of the electro-thermal coupled virtual power plant; S_{G,i}_{_{B}} represents a collection of all thermal generators located at the node iB; S_{BUS} and S_{BR} represent a collection of all nodes and a collection of all branches of the power distribution network in the electric section of the electro-thermal coupled virtual power plant, respectively; S_{ES} represents a collection of all batteries in the electric section of the electro-thermal coupled virtual power plant; Pₜ^{L,i}^{_{B}} represents an electric load power at the node iB at the scheduling time t; PTDF_{t,i}_{_{B}} represents a power transmission distribution factor of the node iB to a distribution network branch l, which is calculated by a direct current power flow equation in a power system network analysis technique: pₜ^{t,BR} represents a power of the distribution network branch l in the electric section of the electro-thermal coupled virtual power plant at the scheduling time t; pₜ^{iNET,i}^{_{B}} represents a net outflow power of the node iB of the power distribution network in the electric section of the electro-thermal coupled virtual power plant at the scheduling time t; η^{c,i}^{_{E}} and η^{dc,i}^{_{E}} represent a charging efficiency and a discharging efficiency of the iEth battery in the electric section of the electro-thermal coupled virtual power plant, respectively, the values of η^{c,i}^{_{E}} and η^{dc,i}^{_{E}} depend on the factory specification of the battery. In an embodiment of the present disclosure, the values of η^{c,i}^{_{E}} and η^{dc,i}^{_{E}} are 0.95 and 0.95 respectively. Δt represents an interval of scheduling times; sⁱ^{_{E}} represents a self-loss rate of the iEth battery in the electric section of the electro-thermal coupled virtual power plant, the value depends on the factory specification of the battery, in an embodiment of the present disclosure, the value is 0.999. Pₜⁱ^{_{W}}^{,pre} represents a prediction power of the iWth new energy generator set in the electric section of the electro-thermal coupled virtual power plant at the scheduling time t; Pₘₐₓⁱ^{_{G}} and Pₘᵢₙⁱ^{_{G}} represents a maximum active power and a minimum active power of the iGth thermal generator in the electric section of the electro-thermal coupled virtual power plant, respectively, which can be obtained from the device specification; and Pₘₐₓⁱ^{_{EB}} and Pₘᵢₙⁱ^{_{EB}} represent a maximum active power and a minimum active power of the iEBth electric boiler in a coupling element of the electro-thermal coupled virtual power plant, respectively, which can be obtained from the device specification.

(222) The constrains of the coupling element are:

$${h}_{t}^{{i}_{EB}} = {η}^{{i}_{EB}} {p}_{t}^{{i}_{EB}} , ∀ {i}_{E B} ∈ {S}_{E B}$$

$$0 \leq {λ}_{t}^{{i}_{C} , k} \leq 1 , ∀ k ∈ E {P}^{{i}_{C}} , ∀ t ∈ ϒ , ∀ {i}_{C} ∈ {S}_{C H P}$$

$${\sum }_{k ∈ {EP}^{i}} {λ}_{t}^{{i}_{C} , k} = 1 , ∀ t ∈ ϒ , ∀ {i}_{C} ∈ {S}_{CHP}$$

$${p}_{t}^{{i}_{C}} = {\sum }_{k ∈ E {P}^{{i}_{C}}} {λ}_{t}^{{i}_{C} , k} {P}^{{i}_{C} , k} , {h}_{t}^{{i}_{C}} = {\sum }_{k ∈ E {P}^{{i}_{C}}} {λ}_{t}^{{i}_{C} , k} {H}^{{i}_{C} , k} , ∀ t ∈ ϒ , ∀ {i}_{C} ∈ {S}_{CHP}$$

$${H}_{min}^{{i}_{G B}} \leq {h}_{t}^{{i}_{G B}} \leq {H}_{max}^{{i}_{G B}}$$

where ηⁱ^{_{EB}} represents an efficiency of the iEBth electric boiler in the coupling element of the electro-thermal coupled virtual power plant; hₜⁱ^{_{EB}} represents a thermal output power of the iEBth electric boiler at the scheduling time t; EPⁱ^{_{C}} represents a collection of all poles of the feasible domain of the iCth combined heat and power component; λₜⁱ^{_{C}}^{,k} represents a scale factor of a pole k of the iCth combined heat and power component; Pₜⁱ^{_{C}}^{,k} represent an electrical power and a thermal power corresponding to the pole k of the iCth combined heat and power component, respectively. For back-pressure combined heat and power components, the number of poles in the feasible domain is usually 2, the feasible domain is a straight line, and the electro-thermal ratio is usually fixed. For pumped condensing combined heat and power components, the number of poles in the feasible domain is 3 or 4 because the pumping volume can be adjusted. Hₘₐₓⁱ^{_{GB}} and Hₘₘᵢₙⁱ^{_{GB}} represent a maximum thermal power and a minimum thermal power of the iGBth gas boiler, respectively, which can be obtained from the device specification.

(223) The constraints of the heating section after data-driven equivalence are obtained by the following processes.

The equivalence model in the heating section of the electro-thermal coupled virtual power plant obtained in step (1) is determined as the constraints of the heating section after data-driven equivalence by

$$S V {M}_{n} ( {h}_{t}^{1} , {h}_{t}^{2} , … , {h}_{t}^{N H S} , {τ}_{t} ) = 0$$

where a superscript NHS represents a total number of heat sources in the heating section of the electro-thermal coupled virtual power plant; jᵢ_{_{d}}_{,t}^{j} represents a thermal output power of a jth heat source in the heating section in an idth data at the scheduling time t, and τᵢ_{_{d}}_{,t} represents the outdoor temperature in the idth data at the scheduling time t.

In step III, equivalent aggregation of the electro-thermal coupled virtual power plant is realized by solving the computing model for equivalent aggregation of the electro-thermal coupled virtual power plant, which includes: obtaining optimal values of pₜ, p̅ₜ, eₜ, ēₜ, r^{d} and r^{u} by solving the optimal computing model constitute of the objective function and the constraints in step II for equivalent aggregation of the electro-thermal coupled virtual power plant by a column-and-constraint generation process, and determining optimal values of pₜ, p̅ₜ, eₜ, ēₜ, r^{d} and r^{u} as final values of a lower power limit, an upper power limit, a lower energy limit, an upper energy limit, a lower limit of power change rate, and an upper limit of power change rate of an interconnection line between the electro-thermal coupled virtual power plant and a superior power grid. The column-constraint generation method used in this step, a common technique for solving robust optimization problems, was first proposed in the 2013 in the paper “Solving two-stage robust optimization problems using a column-and-constraint generation method”.

The present disclosure provides the equivalent aggregation method for the electro-thermal coupled virtual power plant, it firstly obtains the linear equivalent constraints of the heating section by a data driving process, and then adds the linear equivalent constraints of the heating section to the aggregation model of the electro-thermal coupled virtual power plant, to obtain the equivalent aggregation model for the electro-thermal coupled virtual power plant driven by model and data. Compared with the existing patent application No. 201911094785.2, the method of the present disclosure firstly obtains the linear equivalent constraints of the heating section in step I by the data driving process, and then adds the linear equivalent constraints of the heating section into the aggregation model of the electro-thermal coupled virtual power plant to obtain the equivalent aggregation model of the virtual power plant in step II, and finally realizes the equivalent aggregation for the electro-thermal coupled virtual power plant driven by model and data. Therefore, the method of the present disclosure overcomes the disadvantage of inaccurate aggregation results caused by the difficulty of obtaining parameters accurately in the model driving method in the related art.

Compared with the existing technology, the equivalent aggregation method for the electro-thermal coupled virtual power plant of the present disclosure uses a data-model driving process to perform equivalent aggregation for the electro-thermal coupled virtual power plant, which organically combines the reliability of the model driving algorithm and the adaptiveness of the data driving algorithm, so as to overcome the problem of inaccurate heating section model in the electro-thermal coupled virtual power plant and achieve more accurate equivalent aggregation.

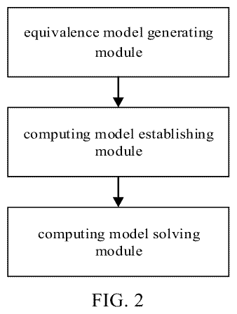

Corresponding to the equivalent aggregation method for the electro-thermal coupled virtual power plant, an embodiment of the present disclosure provides an equivalent aggregation apparatus for the electro-thermal coupled virtual power plant. The structure of the apparatus is shown in FIG. 2, and the apparatus includes:
an equivalence model generating module configured to obtain an equivalence model in a heating section of the electro-thermal coupled virtual power plant by training a support vector machine;
a computing model establishing module configured to establish a computing model for equivalent aggregation of the electro-thermal coupled virtual power plant; and
a computing model solving module configured to realize equivalent aggregation of the electro-thermal coupled virtual power plant by solving the computing model for equivalent aggregation of the electro-thermal coupled virtual power plant.

An embodiment of the present disclosure provides an electronic device. The electronic device includes:
a memory configured to store instructions executable by a computer;
a processor configured to, in sequence:
obtain an equivalence model in a heating section of the electro-thermal coupled virtual power plant by training a support vector machine;
establish a computing model for equivalent aggregation of the electro-thermal coupled virtual power plant; and
realize equivalent aggregation of the electro-thermal coupled virtual power plant by
solving the computing model for equivalent aggregation of the electro-thermal coupled virtual power plant.

An embodiment of the present disclosure provides a non-volatile computer-readable storage medium having computer programs stored thereon. The computer programs are configured to cause a computer to:
obtain an equivalence model in a heating section of the electro-thermal coupled virtual power plant by training a support vector machine;
establish a computing model for equivalent aggregation of the electro-thermal coupled virtual power plant; and
realize equivalent aggregation of the electro-thermal coupled virtual power plant by
solving the computing model for equivalent aggregation of the electro-thermal coupled virtual power plant.

It should be noted that in embodiments of the present disclosure, the processor referred to may be a central processing unit (CPU), a general purpose processor, a digital signal processor (DSP), an application specific integrated circuit (ASIC), a field programmable gate array (FPGA) or other programmable logic devices, discrete gates or transistor logic devices, discrete hardware components, etc. The general purpose processor may be a microprocessor, or any conventional processor, etc. The memory may be used to store the computer programs and/or modules, and the processor performs various functions of equivalent aggregation of the electro-thermally coupled virtual power plant by running or executing the computer programs and/or modules stored in the memory, and by calling data stored in the memory. The memory may primarily include a storage program area and a storage data area. The storage program area may store an operating system, at least one application required for the function (e.g., sound playback function, image play back function, etc.), etc. The storage data area may store data created by the operating system in the course of running the application, etc. In addition, the memory may include a high-speed random access memory, and a non-volatile memory, such as hard disk, memory, plug-in hard disk, smart media card (SMC), secure digital (SD) card, flash card, at least one disk memory device or flash memory device.

Based on such understanding, the present disclosure implements all or part of the processes in the method of the above embodiments, which may also be accomplished by means of computer programs to instruct the relevant hardware. The computer programs may be stored in a computer readable storage medium. When the computer programs are executed by a processor, the steps of each of the above method embodiments are implemented. The computer programs include computer program codes in the form of source codes, object codes, executable files or some intermediate form, etc. The computer readable medium may include: any entity or device capable of carrying the computer program codes, a recording medium, a USB flash drive, a mobile hard disk, a diskette, a CD, a computer memory, a read only memory (ROM), a random access memory (RAM), an electric carrier signal, a telecommunication signal and a software distribution medium, etc. It is noted that the above described embodiments of the device are merely schematic, wherein the units described as separate components illustrated may or may not be physically separated, and the components displayed as units may or may not be physical units, i.e., they may be located in one place or may be distributed to a plurality of network units. Some or all of these modules can be selected according to practical needs to achieve the purpose of the solution of the embodiment. In addition, the connection relation between the modules in the attached drawings of the device embodiments provided in the present disclosure indicates that they are communicatively connected with each other, which can be specifically implemented by one or more communication buses or signal lines, and understood and implemented by those skilled in the art without inventive works.

The above described are preferred embodiments of the present disclosure, and it should be noted that for those skilled in the art, a number of improvements and embellishments can be made without departing from the principles of the present disclosure, which are also considered to be within the scope of protection of the present disclosure.

What is claimed is:

1. An equivalent aggregation method for an electro-thermal coupled virtual power plant, comprising:
obtaining an equivalence model in a heating section of the electro-thermal coupled virtual power plant by training a support vector machine;
establishing a computing model for equivalent aggregation of the electro-thermal coupled virtual power plant; and
realizing the equivalent aggregation of the electro-thermal coupled virtual power plant by solving the computing model for the equivalent aggregation of the electro-thermal coupled virtual power plant.

2. The method of claim 1, wherein obtaining the equivalence model in the heating section of the electro-thermal coupled virtual power plant by training the support vector machine comprises:
(1) based on historical operation data of the heating section of the electro-thermal coupled virtual power plant or using a heating section simulation model built using a simulation model, obtaining N operation data, establishing an operation data set X={X₁, X₂, . . . , X_{N}}, wherein {Xᵢ_{_{d}}|1≤i_{d}≤N}, X₁, X₂, . . . , X_{N}, determining heating powers and outdoor temperatures of all heat sources in the heating section at all times from the operation data set X as features, wherein a subscript i_{d} represents an operation data serial number, i_{d}=1, 2, . . . , N, Xᵢ_{_{d}}=[hᵢ_{_{d}}_{,t}¹, hᵢ_{_{d}}_{,t}², . . . , hᵢ_{_{d}}_{,t}^{NHS}, τᵢ_{_{d}}_{,t}]^{T}, t∈T, a superscript T represents a matrix transposition, NHS represents a total number of heat sources in the heating section of the electro-thermal coupled virtual power plant, hᵢ_{_{d}}_{,t}^{j} represents a thermal output power of a j^{th} heat source in the heating section in the i_{d}^{th} operation data at a scheduling time t, τᵢ_{_{d}}_{,t}^{j} represents an outdoor temperature in the i_{d}^{th} operation data at the scheduling time t;
(2) obtaining N_{TE} operation data from the historical operation data of the heating section of the electro-thermal coupled virtual power plant or the heating section simulation model built using the simulation model, establishing a test data set X_{TE}={X_{TE}, X_{TE}, . . . , X_{N}_{_{TE}}^{TE}} by using the N_{TE} operation data as test data, determining heating powers and outdoor temperatures of all heat sources in the heating section at all times from the test data set X_{TE} as features;
(3) assigning initial labels y⁰=[y₁, y₂, . . . , yᵢ_{_{d}}, . . . , y_{N}]^{T} to each data in the operation data set X in step (1), wherein the subscript i_{d} represents the operation data serial number, i_{d}=1, 2, . . . , N, yᵢ_{_{d}} represents a label corresponding to the i_{d}^{th} operation data, and the superscript T represents the matrix transposition: judging a temperature inside all heat load chambers in the heating section of the electro-thermal coupled virtual power plant under conditions of the operation data set,
in case that the temperature inside all the heat load chambers reaches a temperature threshold under operation conditions corresponding to the i_{d}^{th} operation data Xᵢ_{_{d}}, assigning label 0 to the i_{d}^{th} operation data by yᵢ_{_{d}}=0, and
in case that the temperature inside at least one heat load chamber in the electro-thermal coupled virtual power plant does not reach the temperature threshold, assigning label 1 to the i_{d}^{th} operation data by yᵢ_{_{d}}=1;
(4) assigning labels y_{TE}=[y₁, y₂, . . . , yᵢ_{_{TE}} . . . , y_{N}]^{T} to the test data set generated in step (2), wherein a subscript TE represents a test data serial number, i_{TE}=1, 2, . . . , N_{TE}, and a superscript T represents the matrix transposition; and judging a temperature inside heat load chambers in the heating section under operation conditions of the test data set,
in case that the temperature inside all the heat load chambers reaches the temperature threshold under operation conditions corresponding to the i_{TE}^{th} test data, assigning label 0 to the i_{TE}^{th} test data, and
in case that the temperature inside at least one heat load chamber in the electro-thermal coupled virtual power plant does not reach the temperature threshold, assigning label 1 to the i_{TE}^{th} test data;
(5) setting an equivalence model accuracy threshold ε_{D} and a maximum training number nₘₐₓ, and performing single classification training on the operation data set X in step (1) comprising:
setting a total training number n=1, inputting the operation data set X to the support vector machine SVM₁, outputting classification results for each data in the operation data set X by the support vector machine SVM₁, and obtaining a classification model SVM₁=(w₁, b₁), where w₁ represents a hyper-plane normal vector of the classification model in the support vector machine, and b₁ represents a hyper-plane intercept of the classification model in the support vector machine;
(6) using the test data set X_{TE}={X₁^{TE}, X₂^{TE}, . . . , X_{N}_{_{TE}}^{TE}} generated in step (2) and the labels y_{TE}=[y₁, y₂, . . . , yᵢ_{_{TE}} . . . , Y_{N}]^{T} assigned in step (4), calculating a classification accuracy rate ε_{R} of the support vector machine SVM₁=(w₁, b₁) when n=1 by a following formula:
$${ε}_{R} = \frac{{N}_{c o r r e c t}}{{N}_{t o t a l}} \times 100 \% ,$$
where Nₜₒₜₐₗ is a total number of data points in the test data set X_{TE} whose labels are 1, N_{correct} is a number of samples correctly classified, and N_{correct} is a total number of data points in the test data set X_{TE} whose labels are 1 and classified as category 1 by the classification model SVM₁;
(7) comparing the ε_{R} with the equivalence model accuracy threshold ε_{D},
in case that ε_{R}<ε_{D} and n<nₘₐₓ, executing step (8), and
in case that ε_{R}≥ε_{D} or n≥nₘₐₓ, using a support vector machine SVMₙ as the equivalence model in the heating section of the electro-thermal coupled virtual power plant, and executing step (2);
(8) adding the n in step (5) by 1 and reassign labels yⁿ={y₁ⁿ, y₂ⁿ, . . . , y_{N}ⁿ} to the operation data set X in step (1), where
$${y}_{{i}_{d}}^{n} = \{ \begin{matrix}{y}_{{i}_{d}}^{n - 1} , {i}_{d} ∉ {S}_{w r o n g} \\ max \{ {y}_{{i}_{d}}^{n - 1} \} + 1 , {i}_{d} ∈ {S}_{w r o n g}\end{matrix} ,$$
S_{wrong} represents a set consisting of serial numbers of the samples classified incorrectly in step (6), S_{wrong}={i|yₜ⁰=1, SVMₙ(X₁)<1}, i_{d} represents the data serial number of the operation data set;
(9) classifying the operation data set X in step (1) and the labels yⁿ in step (8), to obtain an (n+1)^{th} classification model SVMₙ₊₁=(w₁ⁿ⁺¹, b₁ⁿ⁺¹, . . . , w_{(n+1)(n+2)/2}ⁿ⁺¹, b_{(n+1)(n+2)/2}ⁿ⁺¹), where wₜⁿ⁺¹, bₜⁿ⁺¹ represent an i^{th} hyper-plane normal vector and an i^{th} hyper-plane intercept in the (n+1)^{th} classification model, respectively;
(10) for the (n+1)^{th} classification model SVMₙ₊₁, testing an accuracy rate of the (n+1)^{th} classification model SVMₙ₊₁ using the test data set X_{TE}={X₁^{TE}, X₂^{TE}, . . . , X_{N}_{_{TE}}^{TE}} generated in step (2) and the labels y_{TE}=[y₁, y₂ . . . , y_{N}]^{T} assigned in step (4), and calculating a classification accuracy rate ε_{R} of the (n+1)^{th} classification model SVMₙ₊₁ using the method in step (6), where Nₜₒₜₐₗ represents a total number of data points whose labels are 1 in X_{TE}, N_{correct} represents a total number of data points in the test data set X_{TE} whose labels are 1 and classified as category 1 by the classification model SVM₁, and when SVMₙ₊₁(Xᵢ)>0 and yᵢ⁰=1, the data point i is considered to be accurately classified; and
(11) configuring n=n+1, comparing ε_{R} in step (10) with the equivalence model accuracy threshold ε_{D},
in case that ε_{R}<ε_{D} and n<nₘₐₓ, returning to step (8), and
in case that ε_{R}≥ε_{D} or n≥nₘₐₓ, using the support vector machine SVMₙ as the equivalence model in the heating section of the electro-thermal coupled virtual power plant, and returning to step (2).

3. The method of claim 2, wherein the heat sources includes combined heat and power components, electric boilers and gas boilers.

4. The method of claim 1, wherein establishing the computing model for equivalent aggregation of the electro-thermal coupled virtual power plant comprises using:
(21) an objective function of the computing model for equivalent aggregation of the electro-thermal coupled virtual power plant:
$${min}_{y} {\sum }_{t ∈ ϒ} ( {c}_{t}^{p , min} {\underline{p}}_{t} - {c}_{t}^{p , max} {\overline{p}}_{t} + {c}_{t}^{e , min} {\underline{e}}_{t} - {c}_{t}^{e , max} {\overline{e}}_{t} - {c}_{t}^{r u} {r}_{t}^{u} - {c}_{t}^{r d} {r}_{t}^{d} ) + {max}_{{p}_{t}^{order} ∈ Ω} {min}_{x} {\sum }_{t ∈ ϒ} [ σ ( {δ}_{t}^{+} + {δ}_{t}^{-} ) ]$$
where the objective function is a maximum feasible domain of the computing model of equivalent aggregation of the electro-thermal coupled virtual power plant obtained by aggregation; parameters pₜ, p̅ₜ, eₜ, ēₜ, rₜ^{d} and rₜ^{u} represent a lower power limit, an upper power limit, a lower energy limit, an upper energy limit, a lower limit of a power change rate, and an upper limit of the power change rate of an interconnection line between the electro-thermal coupled virtual power plant and a superior power grid at the scheduling time t, respectively; cₜ^{p,min}, cₜ^{p,max}, cₜ^{e,min}, cₜ^{e,max}, cₜ^{ru} and cₜ^{rd} represent weights of the parameters pₜ, p̅ₜ, eₜ, ēₜ, rₜ^{d} and rₜ^{u}, respectively; values of cₜ^{p,min}, cₜ^{p,max}, cₜ^{e,min}, cₜ^{e,max}, cₜ^{ru} and cₜ^{rd} are determined according to actual operation conditions of the superior power grid;
pₜ^{order} is an active power value of a possible scheduling plan of the superior power grid at the scheduling time t and is a variable to be solved: {pₜ, p̅ₜ, eₜ, ēₜ, r^{u}, r^{d}} represent variables to be calculated for solving an aggregation model of the electro-thermal coupled virtual power plant, these six variables constitute the feasible domain obtained by aggregation, and pₜ^{order} satisfies that
$${\underline{p}}_{t} \leq {p}_{t}^{o r d e r} \leq {\overline{p}}_{t} , t ∈ T , {\underline{e}}_{t} \leq {\sum }_{t = 1}^{t} {p}_{t}^{o r d e r} \leq {\overline{e}}_{t} , t ∈ T , and - {r}^{d} \leq {p}_{t}^{o r d e r} - {p}_{t - 1}^{o r d e r} \leq {r}^{u} , t ∈ T ,$$
where σ represents a large positive number, such as 10⁶, δₜ⁺, represents an auxiliary variable for a power positive deviation of the interconnection line, δₜ⁻, represents an auxiliary variable for a power negative deviation of the interconnection line,
y represents a first stage decision variable for an optimal computing model for equivalent aggregation of the electro-thermal coupled virtual power plant, X represents a second stage decision variable for the optimal computing model: a column vector consisting of the first stage decision variables y is y=[pₜ, p̅ₜ, eₜ, ēₜ, r^{u}, r^{d}], and a column vector consisting of the second stage decision variables x is x=[pₜⁱ^{_{G}}, pₜⁱ^{_{W}}, pₜ^{CHP,i}^{_{c}}, hₜ^{CHP,i}^{_{c}}, pₜ^{c,i}^{_{E}}, pₜ^{dc,i}^{_{E}}, eₜⁱ^{_{E}}, hₜⁱ^{_{GB}}, pₜⁱ^{_{EB}}, δₜ⁺, δₜ⁻],
where pₜⁱ^{_{G}} represents a power output of an i_{G}^{th} thermal generator in an electric section of the electro-thermal coupled virtual power plant at the scheduling time t, pₜ^{W,i}^{_{w}} represents an actual power output of an i_{W}^{th} new energy generator set in the electric section of the electro-thermal coupled virtual power plant at the scheduling time t, pₜ^{CHP,i}^{_{C}} and hₜ^{CHP,i}^{_{C}} represent an electricity output and a heat output of an i_{C}^{th} combined heat and power component in a coupling section of the electro-thermal coupled virtual power plant at the scheduling time t, respectively; pₜ^{c,i}^{_{E}} and pₜ^{dc,i}^{_{E}} represent a charging power and a discharging power of an i_{E}^{th} battery in the electric section of the electro-thermal coupled virtual power plant at the scheduling time t, respectively; eₜⁱ^{_{E}} represents an energy stored by the i_{E}^{th} battery in the electric section of the electro-thermal coupled virtual power plant at the scheduling time t; hₜⁱ^{_{GB}} represents a heating power of an i_{GB}^{th} gas boiler in the heating section of the electro-thermal coupled virtual power plant at the scheduling time t; pₜⁱ^{_{EB}} represents a power consumption of an i_{EB}^{th} electric boiler in the heating section of the electro-thermal coupled virtual power plant at the scheduling time t; and in the objective function, except for δₜ⁺, δₜ⁻, the weights of other variables in the objective function are 0;
(22) constraints of the optimal computing model for equivalent aggregation of the electro-thermal coupled virtual power plant.

5. The method of claim 4, wherein the constraints comprise:
(221) constrains of the electric section:
$${p}_{t}^{tie} + {\sum }_{{i}_{G} ∈ {S}_{G}} {p}_{t}^{{i}_{G}} + {\sum }_{{i}_{W} ∈ {S}_{W}} {p}_{t}^{{i}_{W}} + {\sum }_{{i}_{C} ∈ {S}_{CHP}} {p}_{t}^{{i}_{C}} + {\sum }_{{i}_{E} ∈ {S}_{E S}} ( {p}_{t}^{d c , {i}_{E}} - {p}_{t}^{c , {i}_{E}} ) = {\sum }_{{i}_{B} ∈ {S}_{B U S}} {P}_{t}^{L , {i}_{B}} + {\sum }_{{i}_{E B} ∈ {S}_{E B}} {p}_{t}^{{i}_{E B}} , ∀ t ∈ ϒ$$
$${p}_{t}^{l , BR} = \vert {\sum }_{n ∈ {S}_{B U S}} P T D {F}_{l , {i}_{B}} \cdot {p}_{t}^{NET , {i}_{B}} \vert , ∀ l ∈ {S}_{B R} , t ∈ ϒ$$
$${p}_{t}^{NET , n} = {\sum }_{{i}_{G} ∈ {S}_{G , {i}_{B}}} {p}_{t}^{{i}_{G}} + {\sum }_{{i}_{W} ∈ {S}_{W , {i}_{B}}} {p}_{t}^{{i}_{W}} + {\sum }_{{i}_{C} ∈ {S}_{CHP , {i}_{B}}} {p}_{t}^{{i}_{C}} + {\sum }_{{i}_{E} ∈ {S}_{ES , {i}_{B}}} ( {p}_{t}^{d c , {i}_{E}} - {p}_{t}^{c , {i}_{E}} ) - {P}_{t}^{L , n} - {\sum }_{{i}_{EB} ∈ {S}_{EB , n}} {p}_{t}^{{i}_{E B}}$$
$${e}_{1}^{{i}_{E}} = {E}_{0}^{{i}_{E}} + ( {η}^{c , {i}_{E}} {p}_{1}^{c , {i}_{E}} - {p}_{1}^{d c , {i}_{E}} / {η}^{d c , {i}_{E}} ) Δ t , ∀ {i}_{E} ∈ {S}_{E S} ,$$
$${e}_{t}^{{i}_{E}} = ( 1 - {s}^{{i}_{E}} ) {e}_{t - 1}^{{i}_{E}} + ( {η}^{c , {i}_{E}} {p}_{t}^{c , {i}_{E}} - \frac{{p}_{t}^{d c , {i}_{E}}}{{η}^{d c , {i}_{E}}} ) Δ t , ∀ t ∈ ϒ ∖ \{ 1 \} , ∀ i ∈ {S}_{E S} .$$
$$0 \leq {p}_{t}^{{i}_{W}} \leq {P}_{t}^{{i}_{W} , pre}$$
$${P}_{min}^{{i}_{G}} \leq {p}_{t}^{{i}_{G}} \leq {P}_{max}^{{i}_{G}}$$
$${P}_{min}^{{i}_{E B}} \leq {p}_{t}^{{i}_{E B}} \leq {P}_{max}^{{i}_{E B}}$$
where S_{G}, S_{W}, S_{CHP}, S_{ES}, S_{L} and S_{EB} represent a collection of thermal generators, a collection of new energy generator sets, a collection of combined heat and power components, a collection of batteries, a collection of electric loads, and a collection of electric boilers in the electro-thermal coupled virtual power plant, respectively; a subscript i_{B} of device collection represents a collection of all devices connected to a node is of a power distribution network in the electric section of the electro-thermal coupled virtual power plant; S_{G,i}_{_{B}} represents a collection of all thermal generators located at the node i_{B}; S_{BUS} and S_{BR} represent a collection of all nodes and a collection of all branches of the power distribution network in the electric section of the electro-thermal coupled virtual power plant, respectively; S_{ES} represents a collection of all batteries in the electric section of the electro-thermal coupled virtual power plant; Pₜ^{L,i}^{_{B}} represents an electric load power at the node i_{B} at the scheduling time t; PTDF_{l,i}_{_{B}}, represents a power transmission distribution factor of the node is to a distribution network branch l, which is calculated by a direct current power flow equation in a power system network analysis technique; pₜ^{l,BR} represents a power of the distribution network branch l in the electric section of the electro-thermal coupled virtual power plant at the scheduling time t; pₜ^{NET,i}^{_{B}} represents a net outflow power of the node is of the power distribution network in the electric section of the electro-thermal coupled virtual power plant at the scheduling time t; η^{c,i}^{_{E}} and η^{dc,i}^{_{E}} represent a charging efficiency and a discharging efficiency of the i_{E}^{th} battery in the electric section of the electro-thermal coupled virtual power plant, respectively, Δt represents an interval of scheduling times; sⁱ^{_{E}} represents a self-loss rate of the i_{E}^{th} battery in the electric section of the electro-thermal coupled virtual power plant; Pₜⁱ^{_{W}}^{,pre} represents a prediction power of the i_{W}^{th} new energy generator set in the electric section of the electro-thermal coupled virtual power plant at the scheduling time t; Pₘₐₓⁱ^{_{G}} and Pₘᵢₙⁱ^{_{G}} represent a maximum active power and a minimum active power of the i_{G}^{th} thermal generator in the electric section of the electro-thermal coupled virtual power plant, respectively; and Pₘₐₓⁱ^{_{EB}} and Pₘᵢₙⁱ^{_{EB}} min represent a maximum active power and a minimum active power of the iEBth electric boiler in a coupling element of the electro-thermal coupled virtual power plant, respectively;
(222) constrains of the coupling element:
$${h}_{t}^{{i}_{EB}} = {η}^{{i}_{EB}} {p}_{t}^{{i}_{EB}} , ∀ {i}_{E B} ∈ {S}_{E B}$$
$$0 \leq {λ}_{t}^{{i}_{C} , k} \leq 1 , ∀ k ∈ E {P}^{{i}_{C}} , ∀ t ∈ ϒ , ∀ {i}_{C} ∈ {S}_{C H P}$$
$${\sum }_{k ∈ {EP}^{i}} {λ}_{t}^{{i}_{C} , k} = 1 , ∀ t ∈ ϒ , ∀ {i}_{C} ∈ {S}_{CHP}$$
$${p}_{t}^{{i}_{C}} = {\sum }_{k ∈ E {P}^{{i}_{C}}} {λ}_{t}^{{i}_{C} , k} {P}^{{i}_{C} , k} , {h}_{t}^{{i}_{C}} = {\sum }_{k ∈ E {P}^{{i}_{C}}} {λ}_{t}^{{i}_{C} , k} {H}^{{i}_{C} , k} , ∀ t ∈ ϒ , ∀ {i}_{C} ∈ {S}_{CHP}$$
$${H}_{min}^{{i}_{G B}} \leq {h}_{t}^{{i}_{G B}} \leq {H}_{max}^{{i}_{G B}}$$
where ηⁱ^{_{EB}} represents an efficiency of the i_{EB}^{th} electric boiler in the coupling element of the electro-thermal coupled virtual power plant; hₜⁱ^{_{EB}} represents a thermal output power of the iEBth electric boiler at the scheduling time t; EPⁱ^{_{C}} represents a collection of all poles of the feasible domain of the i_{C}^{th} combined heat and power component; λₜⁱ^{_{C}}^{,k} represents a scale factor of a pole k of the i_{C}^{th} combined heat and power component; Pⁱ^{_{C}}^{,k} and Hⁱ^{_{C}}^{,k} represent an electrical power and a thermal power corresponding to the pole k of the i_{G}^{th} combined heat and power component, respectively; Hₘₐₓⁱ^{_{GB}} and Hₘᵢₙⁱ^{_{GB}} represent a maximum thermal power and a minimum thermal power of the i_{GB}^{th} gas boiler, respectively;
(223) constraints of the heating section after data-driven equivalence:
determining the equivalence model in the heating section of the electro-thermal coupled virtual power plant as the constraints of the heating section after data-driven equivalence by
SVMₙ(hₜ¹,hₜ², . . . , hₜ^{NHS},τₜ)=0
where a superscript NHS represents a total number of heat sources in the heating section of the electro-thermal coupled virtual power plant; hᵢ_{_{d}}_{,t}^{j}, represents a thermal output power of a j^{th} heat source in the heating section in an i_{d}^{th} data at the scheduling time t, and τᵢ_{_{d}}_{,t} represents the outdoor temperature in the i_{d}^{th} data at the scheduling time t.

6. The method of claim 5, wherein a value of η^{c,i}^{_{E}} is 0.95, and a value of η^{dc,i}^{_{E}} is 0.95.

7. The method of claim 5, wherein a value of sⁱ^{_{E}} is 0.999.

8. The method of claim 5, wherein the combined heat and power component is a back-pressure combined heat and power component, and the number of poles in a feasible domain is 2.

9. The method of claim 5, wherein the combined heat and power component is a pumped condensing combined heat and power component, and the number of poles in a feasible domain is 3 or 4.

10. The method of claim 1, wherein realizing equivalent aggregation of the electro-thermal coupled virtual power plant by solving the computing model for equivalent aggregation of the electro-thermal coupled virtual power plant comprises:
realizing equivalent aggregation of the electro-thermal coupled virtual power plant by solving an optimal computing model for equivalent aggregation of the electro-thermal coupled virtual power plant by a column-and-constraint generation method, and obtaining optimal values of pₜ, p̅ₜ, eₜ, ēₜ, r^{d} and r^{u} as final values of a lower power limit, an upper power limit, a lower energy limit, an upper energy limit, a lower limit of power change rate, and an upper limit of power change rate of an interconnection line between the electro-thermal coupled virtual power plant and a superior power grid.

11. An electronic device, comprising:
a memory, configured to store instructions executable by a computer;
a processor, configured to:
obtain an equivalence model in a heating section of an electro-thermal coupled virtual power plant by training a support vector machine;
establish a computing model for equivalent aggregation of the electro-thermal coupled virtual power plant; and
realize equivalent aggregation of the electro-thermal coupled virtual power plant by solving the computing model for equivalent aggregation of the electro-thermal coupled virtual power plant.

12. The electronic device of claim 11, wherein the processor is configured to:
(1) based on historical operation data of the heating section of the electro-thermal coupled virtual power plant or using a heating section simulation model built using a simulation model, obtain N operation data, establish an operation data set X={X₁, X₂, . . . , X_{N}}, wherein {Xᵢ_{_{d}}|1≤i_{d}≤N}, X₁, X₂, . . . , X_{N}, determine heating powers and outdoor temperatures of all heat sources in the heating section at all times from the operation data set X as features, wherein a subscript i_{d} represents an operation data serial number, i_{d}=1, 2, . . . , N, Xᵢ_{_{d}}=[hᵢ_{_{d}}_{,t}¹, hᵢ_{_{d}}_{,t}², . . . , hᵢ_{_{d}}_{,t}^{NHS}, τᵢ_{_{d}}_{,t}]^{T}, t∈T, a superscript T represents a matrix transposition, NHS represents a total number of heat sources in the heating section of the electro-thermal coupled virtual power plant, hᵢ_{_{d}}_{,t}^{j}, represents a thermal output power of a j^{th} heat source in the heating section in the i_{d}^{th} operation data at a scheduling time t, τᵢ_{_{d}}_{,t} represents an outdoor temperature in the i_{d}^{th} operation data at the scheduling time t;
(2) obtain N_{TE} operation data from the historical operation data of the heating section of the electro-thermal coupled virtual power plant or the heating section simulation model built using the simulation model, establish a test data set X_{TE}={X₁^{TE}, X₂^{TE}, X₂^{TE}, . . . , X_{N}_{_{TE}}^{TE}} by using the N_{TE} operation data as test data, determine heating powers and outdoor temperatures of all heat sources in the heating section at all times from the test data set X_{TE} as features;
(3) assign initial labels y⁰=[y₁, y₂, . . . , yᵢ_{_{d}}, . . . , y_{N}]^{T} to each data in the operation data set X in step (1), wherein the subscript i_{d} represents the operation data serial number, i_{d}=1, 2, . . . , N, yᵢ_{_{d}} represents a label corresponding to the i_{d}^{th} operation data, and the superscript T represents the matrix transposition: judging a temperature inside all heat load chambers in the heating section of the electro-thermal coupled virtual power plant under conditions of the operation data set,
in case that the temperature inside all the heat load chambers reaches a temperature threshold under operation conditions corresponding to the i_{d}^{th} operation data Xᵢ_{_{d}}, assigning label 0 to the i_{d}^{th} operation data by yᵢ_{_{d}}=0, and
in case that the temperature inside at least one heat load chamber in the electro-thermal coupled virtual power plant does not reach the temperature threshold, assigning label 1 to the i_{d}^{th} operation data by yᵢ_{_{d}}=1;
(4) assign labels y_{TE}=[y₁, y₂, . . . , yᵢ_{_{E}} . . . , y_{N}]^{T} to the test data set generated in step (2), wherein a subscript TE represents a test data serial number, i_{TE}=1, 2, . . . , N_{TE}, and a superscript T represents the matrix transposition; and judging a temperature inside heat load chambers in the heating section under operation conditions of the test data set,
in case that the temperature inside all the heat load chambers reaches the temperature threshold under operation conditions corresponding to the i_{TE}^{th} test data, assigning label 0 to the i_{TE}^{th} test data, and
in case that the temperature inside at least one heat load chamber in the electro-thermal coupled virtual power plant does not reach the temperature threshold, assigning label 1 to the i_{TE}^{th} test data;
(5) set an equivalence model accuracy threshold ε_{D} and a maximum training number nₘₐₓ, and perform single classification training on the operation data set X in step (1) comprising:
setting a total training number n=1, inputting the operation data set X to the support vector machine SVM₁, outputting classification results for each data in the operation data set X by the support vector machine SVM₁, and obtaining a classification model SVM₁=(w₁, b₁), where w₁ represents a hyper-plane normal vector of the classification model in the support vector machine, and b₁ represents a hyper-plane intercept of the classification model in the support vector machine;
(6) use the test data set X_{TE}={X₁^{TE}, X₂^{TE}, . . . , X_{N}_{_{TE}}^{TE}} generated in step (2) and the labels y_{TE} [y₁, y₂, . . . , Yᵢ_{_{E}} . . . , y_{N}]^{T} assigned in step (4), calculating a classification accuracy rate ε_{R} of the support vector machine SVM₁=(w₁, b₁) when n=1 by a following formula:
$${ε}_{R} = \frac{{N}_{c o r r e c t}}{{N}_{t o t a l}} \times 100 \% ,$$
where Nₜₒₜₐₗ is a total number of data points in the test data set X_{TE} whose labels are 1, N_{correct} is a number of samples correctly classified, and N_{correct} is a total number of data points in the test data set X_{TE} whose labels are 1 and classified as category 1 by the classification model SVM₁;
(7) compare the ε_{R} with the equivalence model accuracy threshold ε_{D},
in case that ε_{R}<ε_{D} and n<nₘₐₓ, executing step (8), and
in case that ε_{R}≥ε_{D} or n≥nₘₐₓ, using a support vector machine SVMₙ as the equivalence model in the heating section of the electro-thermal coupled virtual power plant, and executing step (2);
(8) add the n in step (5) by 1 and reassign labels yⁿ={y₁ⁿ, y₂ⁿ, . . . , y_{N}ⁿ} to the operation data set X in step (1), where
$${y}_{{i}_{d}}^{n} = \{ \begin{matrix}{y}_{{i}_{d}}^{n - 1} , {i}_{d} ∉ {S}_{w r o n g} \\ max \{ {y}_{{i}_{d}}^{n - 1} \} + 1 , {i}_{d} ∈ {S}_{w r o n g}\end{matrix} ,$$
S_{wrong} represents a set consisting of serial numbers of the samples classified incorrectly in step (6), S_{wrong}={i| yᵢ⁰=1, SVMₙ(Xᵢ)<1}, i_{d} represents the data serial number of the operation data set;
(9) classify the operation data set X in step (1) and the labels yⁿ in step (8), to obtain an (n+1)^{th} classification model SVMₙ₊₁=(w₁ⁿ⁺¹, b₁ⁿ⁺¹, . . . , w_{(n+1)(n+2)/2}ⁿ⁺¹, b_{(n+1)(n+2)/2}ⁿ⁺¹), where wᵢⁿ⁺¹, bᵢⁿ⁺¹ represent an i^{th} hyper-plane normal vector and an i^{th} hyper-plane intercept in the (n+1)^{th} classification model, respectively;
(10) for the (n+1)^{th} classification model SVMₙ₊₁, test an accuracy rate of the (n+1)^{th} classification model SVMₙ₊₁ using the test data set X_{TE}={X₁^{TE}, X₂^{TE}, . . . , X_{N}_{_{TE}}^{TE}} generated in step (2) and the labels y_{TE}=[y₁, y₂, . . . , yᵢ_{_{E}} . . . , y_{N}]^{T} assigned in step (4), and calculate a classification accuracy rate ε_{R} of the (n+1)^{th} classification model SVMₙ₊₁ using the method in step (6), where Nₜₒₜₐₗ represents a total number of data points whose labels are 1 in X_{TE}, N_{correct} represents a total number of data points in the test data set X_{TE} whose labels are 1 and classified as category 1 by the classification model SVM₁, and when SVMₙ₊₁(Xᵢ)>0 and yᵢ⁰=1, the data point i is considered to be accurately classified; and
(11) configure n=n+1, comparing ε_{R} in step (10) with the equivalence model accuracy threshold ε_{D},
in case that ε_{R}<ε_{D} and n<nₘₐₓ, returning to step (8), and
in case that ε_{R}≥ε_{D} or n≥nₘₐₓ, using the support vector machine SVMₙ as the equivalence model in the heating section of the electro-thermal coupled virtual power plant, and returning to step (2).

13. The electronic device of claim 11, wherein the processor is configured to use:
(21) an objective function of the computing model for equivalent aggregation of the electro-thermal coupled virtual power plant:
$${min}_{y} {\sum }_{t ∈ ϒ} ( {c}_{t}^{p , min} {\underline{p}}_{t} - {c}_{t}^{p , max} {\overline{p}}_{t} + {c}_{t}^{e , min} {\underline{e}}_{t} - {c}_{t}^{e , max} {\overline{e}}_{t} - {c}_{t}^{r u} {r}_{t}^{u} - {c}_{t}^{r d} {r}_{t}^{d} ) + {max}_{{p}_{t}^{order} ∈ Ω} {min}_{x} {\sum }_{t ∈ ϒ} [ σ ( {δ}_{t}^{+} + {δ}_{t}^{-} ) ]$$
where the objective function is a maximum feasible domain of the computing model of equivalent aggregation of the electro-thermal coupled virtual power plant obtained by aggregation; parameters pₜ, p̅ₜ, eₜ, ēₜ, rₜ^{d} and rₜ^{u} represent a lower power limit, an upper power limit, a lower energy limit, an upper energy limit, a lower limit of a power change rate, and an upper limit of the power change rate of an interconnection line between the electro-thermal coupled virtual power plant and a superior power grid at the scheduling time t, respectively; cₜ^{p,min}, cₜ^{p,max}, cₜ^{e,min}, cₜ^{e,max}, cₜ^{ru} and cₜ^{rd} represent weights of the parameters pₜ, p̅ₜ, eₜ, ēₜ, rₜ^{d} and rₜ^{u}, respectively; values of cₜ^{p,min}, cₜ^{p,max}, cₜ^{e,min}, cₜ^{e,max}, cₜ^{ru} and cₜ^{rd} are determined according to actual operation conditions of the superior power grid;
pₜ^{order} order is an active power value of a possible scheduling plan of the superior power grid at the scheduling time t and is a variable to be solved: {pₜ, p̅ₜ, eₜ, ēₜ, r^{u}, r^{d}} represent variables to be calculated for solving an aggregation model of the electro-thermal coupled virtual power plant, these six variables constitute the feasible domain obtained by aggregation, and pₜ^{order} satisfies that
$${\underline{p}}_{t} \leq {p}_{t}^{o r d e r} \leq {\overline{p}}_{t} , t ∈ T , {\underline{e}}_{t} \leq {\sum }_{t = 1}^{t} {p}_{t}^{o r d e r} \leq {\overline{e}}_{t} , t ∈ T , and - {r}^{d} \leq {p}_{t}^{o r d e r} - {p}_{t - 1}^{o r d e r} \leq {r}^{u} , t ∈ T ,$$
where σ represents a positive number, δₜ⁺ represents an auxiliary variable for a power positive deviation of the interconnection line, δₜ⁻ represents an auxiliary variable for a power negative deviation of the interconnection line,
y represents a first stage decision variable for an optimal computing model for equivalent aggregation of the electro-thermal coupled virtual power plant, x represents a second stage decision variable for the optimal computing model: a column vector consisting of the first stage decision variables y is y=[pₜ, p̅ₜ, eₜ, ēₜ, r^{u}, r^{d}], and a column vector consisting of the second stage decision variables x is x=[pₜⁱ^{_{G}}, pₜⁱ^{_{W}}, pₜ^{CHP,i}^{_{c}}, hₜ^{CHP,i}^{_{c}}, pₜ^{c,i}^{_{E}}, pₜ^{dc,i}^{_{E}}, eₜⁱ^{_{E}}, hₜⁱ^{_{GB}}, pₜⁱ^{_{EB}}, δₜ⁺, δₜ⁻],
where pₜⁱ^{_{G}} represents a power output of an i_{G}^{th} thermal generator in an electric section of the electro-thermal coupled virtual power plant at the scheduling time t, pₜ^{W,i}^{_{W}} represents an actual power output of an i_{W}^{th} new energy generator set in the electric section of the electro-thermal coupled virtual power plant at the scheduling time t, pₜ^{CHP,i}^{_{C}} and hₜ^{CHP,i}^{_{C}} represent an electricity output and a heat output of an i_{C}^{th} combined heat and power component in a coupling section of the electro-thermal coupled virtual power plant at the scheduling time t, respectively; pₜ^{c,i}^{_{E}} and pₜ^{dc,i}^{_{E}} represent a charging power and a discharging power of an i_{E}^{th} battery in the electric section of the electro-thermal coupled virtual power plant at the scheduling time t, respectively; eₜⁱ^{_{E}} represents an energy stored by the i_{E}^{th} battery in the electric section of the electro-thermal coupled virtual power plant at the scheduling time t; hₜⁱ^{_{GB}} represents a heating power of an i_{GB}^{th} gas boiler in the heating section of the electro-thermal coupled virtual power plant at the scheduling time t; pₜⁱ^{_{EB}} represents a power consumption of an i_{EB}^{th} electric boiler in the heating section of the electro-thermal coupled virtual power plant at the scheduling time t; and in the objective function, except for δₜ⁺, δₜ⁻, the weights of other variables in the objective function are 0;
(22) constraints of the optimal computing model for equivalent aggregation of the electro-thermal coupled virtual power plant.

14. The electronic device of claim 11, wherein the processor is configured to:
realize equivalent aggregation of the electro-thermal coupled virtual power plant by solving an optimal computing model for equivalent aggregation of the electro-thermal coupled virtual power plant by a column-and-constraint generation method, and obtain optimal values of pₜ, p̅ₜ, eₜ, ēₜ, rₜ^{d} and rₜ^{u} as final values of a lower power limit, an upper power limit, a lower energy limit, an upper energy limit, a lower limit of power change rate, and an upper limit of power change rate of an interconnection line between the electro-thermal coupled virtual power plant and a superior power grid.

15. A non-transitory computer-readable storage medium having computer programs stored thereon, wherein the computer programs are configured to cause a computer to:
obtain an equivalence model in a heating section of an electro-thermal coupled virtual power plant by training a support vector machine;
establish a computing model for equivalent aggregation of the electro-thermal coupled virtual power plant; and
realize equivalent aggregation of the electro-thermal coupled virtual power plant by solving the computing model for equivalent aggregation of the electro-thermal coupled virtual power plant.
